(19) United States
(12) Patent Application Publication
(10) Pub. No.: US 2009/0274935 A1
(43) Pub. Date: Nov. 5, 2009

(54) Fuel Cell System Designed to Ensure Stability of Operation

(75) Inventors: Tetsuro Kikuchi, Nishio-shi (JP); Kazuo Horibe, Toyota-shi (JP); Hiroyuki Takashima, Aichi-gun (JP); Hidetoshi Kato, Suzuka-shi (JP); Naohiro Takeshita, Toyota-shi (JP)

Correspondence Address: OLIFF & BERRIDGE, PLC, P.O. BOX 320850, ALEXANDRIA, VA, 22320-4850, US

(73) Assignees: DENSO CORPORATION, KARIYA-CITY (JP); TOYOTA JIDOSHA KABUSHIKI KAISHA, TOYOTA-SHI (JP); NIPPON SOKEN, INC., NISHIO-CITY (JP)

(21) Appl. No.: 11/921,390

(22) PCT Filed: Jun. 14, 2005
(86) PCT No.: PCT/JP2005/011225

§ 371 Date: Nov. 30, 2007

(51) Int. Cl. H01M 8/00; H01M 8/04; H01M 2/02; G01R 33/02

(52) U.S. Cl. 429/13; 429/22; 429/34; 324/244

(57) ABSTRACT

A fuel cell control system is provided which is designed to ensure the stability of operation of a fuel cell stack. The system includes a magnetic sensor and a controller. The magnetic sensor works to measure a change in magnetic flux density of magnetic field produced by an electric current as generated by electrochemical reaction taken place in each of fuel cells. The controller is designed to analyze the change in magnetic flux density measured by the magnetic sensor to specify the cause and location resulting in a drop in ability of the fuel cell stack to generate electricity which is to occur partially in the fuel cell stack. The controller takes a predetermined measure to control the operation of the fuel cell stack for eliminating the drop in ability of the fuel cell stack to generate the electricity.

### TECHNICAL FIELD

The present invention relates generally to a fuel cell system designed to monitor the distribution of an electric current in a fuel cell stack using a magnetic sensor, and more particularly to such a system working to determine the cause and location resulting in a drop in ability of a fuel cell stack to generate electricity and take a selected measure to eliminate the cause.

### BACKGROUND ART

Fuel cells, especially solid polymer fuel cells are being developed for use in stationary power systems or mobile power systems for automotive vehicles.

The fuel cell, as is well known in the art, works to convert energy produced by electrochemical reaction of oxygen and hydrogen into electric power. Specifically, the fuel cell is supplied with hydrogen (fuel) and oxygen (air) and induces electrochemical reactions thereof at electrodes which are of the forms:

H₂→2H⁺+2e⁻ Fuel electrode

2H⁺+½O₂+2e⁻→H₂O Air electrode

H₂+½O₂→H₂O Cell

The typical fuel cell is made up of an assembly of an electrolyte film, an air-electrode, and a fuel-electrode which are affixed to opposed surfaces of the electrolyte film and separators retaining the assembly therebetween. The separators are equipped with gas flow paths. The fuel cell is supplied at the air electrode with oxygen and at the fuel electrode with hydrogen to generate electricity. It is usually difficult for a single fuel cell to provide the amount of electricity sufficient for practical use. A plurality of fuel cells are typically assembled into a stack and connected electrically in series to produce a large amount of electricity.

It is one of purposes in operating the fuel cell stack to produce the largest amount of electricity with the smallest possible supply of fuel gas (hydrogen gas) and air (oxygen gas). The solid polymer fuel cell stack usually requires the moisture as a medium for proton transport. To this end, the fuel gas is humidified before supplied to the fuel cell stack.

The reaction in the fuel cell stack creates water. An excess of moisture in the fuel cell stack will, however, be a disturbance of the reaction, thus resulting in a drop in ability of the fuel cell stack to generate the electricity. It is, thus, required to keep the amount of moisture in a limited range in the fuel cell stack.

Each of the fuel cells of the fuel cell stack also requires the amount of moisture to be kept in a limited range. Even though the temperature, pressure, or humidify of the gasses to be supplied to the fuel cell stack is control to keep the operation of the fuel cell stack in a desired condition, any one of the fuel cells may be partially out of required conditions. In such an event, the one of the fuel cells fails to generate a required amount of electricity, thus resulting a decrease in an electricity-generating area thereof. This accelerates the aging of the electricity-generating area, thereby resulting in a decreased total service life of the fuel cell stack. It is, thus, essential to keep the moisture in each of the fuel cells to a required amount.

The operating condition of the fuel cell stack is generally monitored by measuring an output voltage of each of the fuel cells. Specifically, when the output voltage of one of the fuel cells has drops undesirably, it is determined to be now malfunctioning. Japanese First Publication No. 9-259913 teaches a fuel cell system designed to analyze a current distribution in the fuel cell stack to diagnose whether a supply of gas is sufficient or insufficient for the reaction in the fuel cell stack. The fuel cell system works to control the flow rate of the gas to be supplied to the fuel cell stack or electric loads on the fuel cell stack to minimize the breakage of the fuel cell stack. The fuel cell system is capable of monitoring the ability of the fuel cells to generate the electricity, but however, unable to diagnose whether any of the fuel cells is partially failing to generate the electricity or not.

It is therefore a principal object of the invention to provide a fuel cell system working to monitor power generating conditions of a fuel cell stack to ensure the stability of operation thereof.

### BRIEF DESCRIPTION OF DRAWINGS

FIG. 1 is a block diagram which shows a fuel cell system according to the first embodiment of the invention;

FIG. 2 is a perspective view which show a fuel cell stack to be controlled by the fuel cell system of FIG. 1;

FIG. 3 is a partially vertical sectional view which shows the structure of each fuel cell of the fuel cell stack of FIG. 2;

FIG. 4 is a plan view which shows a separator affixed to an air electrode of a fuel cell;

FIG. 5 is a plan view which shows a separator affixed to a fuel electrode of a fuel cell;

FIG. 6 is a plan view which shows an electricity-generating region of a fuel cell;

FIG. 7 is a plan view which shows a magnetic field produced around the electricity-generating region as illustrated in FIG. 6;

FIG. 8 is a plan view which shows a fuel cell in which there is an electrochemical reaction disabled area;

FIG. 9 is a plan view which shows a magnetic field produced around the fuel cell of FIG. 8;

FIG. 10 is a plan view which shows a modification of a separator which is attached to an air electrode of a fuel cell and in which a magnetic sensor is installed;

FIG. 11(a) is a plane view which shows another modification of a separator which is attached to an air electrode of a fuel cell and in which a magnetic sensor is installed;

FIG. 11(b) is a transverse sectional view which shows an internal structure of a fuel cell in which a magnetic sensor is installed;

FIG. 11(c) is a plan view which shows the magnetic sensor installed in the fuel cell of FIG. 11(b);

FIG. 12 is a block diagram which shows a fuel cell system according to the second embodiment of the invention;

FIG. 13 is a plan view which shows a fuel cell stack installed in the fuel cell system of FIG. 12;

FIG. 14 is a plan view which shows a current collector plate at which flows of current, as produced by the fuel cell stack of FIG. 13, connect;

FIG. 15 is a perspective view which shows a magnetic field produced around the current collector plate of FIG. 14;

FIG. 16 is a plan view which shows a current collector plate when a portion of a fuel cell stack has partially failed to generate electricity;

FIG. 17 is a perspective view which shows a magnetic filed produced around the current collector plate of FIG. 16; and

FIG. 18 is a perspective view which shows an insulating plate which is attached to a current collector plate and in which magnetic sensors are installed.

### DISCLOSURE OF INVENTION

### Summary

According to one aspect of the invention, there is provided a fuel cell control apparatus which is designed to diagnose an operating condition of a fuel cell stack to ensure a required amount of electricity. The apparatus comprises: (a) a magnetic sensor working to output a signal as a function of a magnetic flux density of a magnetic field produced around a length of the fuel cell stack through which an electrical current, as generated by electrochemical reaction taken place in each of fuel cells, flows; and (b) a controller designed to analyze the signal outputted from the magnetic sensor to detect a change in the magnetic flux density arising from a drop in ability of the fuel cell stack to generate electricity which is to occur partially in the fuel cell stack. The controller works to take a predetermined measure to control the operation of the fuel cell stack for eliminating the drop in ability of the fuel cell stack to generate the electricity. Specifically, the apparatus is designed to diagnose a partial drop in performance of the fuel cell stack and eliminate such a defect to ensure the stability of operation of the fuel cell stack.

In the preferred mode of the invention, the controller compares a value of the signal outputted from the magnetic sensor with a reference value predetermined on a condition that the fuel cell stack is operating normally to produce a required amount of electricity. When a difference between the value of the signal and the reference value is found, the controller takes the predetermined measure to eliminate the drop in ability of the fuel cell stack.

The magnetic sensor is located to be sensitive to a selected portion of the magnetic field produced around one of the fuel cells.

The magnetic sensor may be affixed to a selected portion of the one of the fuel cells.

The magnetic sensor may alternatively be disposed in a selected portion of the one of the fuel cells.

The magnetic sensor may be disposed at the middle of the length of the fuel cell stack.

Each of the fuel cells is made of a unit including an assembly of an electrolyte film, a fuel electrode, and an air electrode, a fuel-side separator, and an air-side separator. The fuel-side separator and the air-side separator are affixed to the fuel electrode and the air electrode, respectively. The magnetic sensor is disposed on one of the fuel-side separator and the air-side separator.

The magnetic sensor may alternatively be installed inside one of the fuel-side separator and the air-side separator.

When the change in the magnetic flux density is detected, the controller selects one of predetermined measures which corresponds to the selected portion of the magnetic field and performs the one of the predetermined measures to control the operation of the fuel cell stack so as to eliminate the change in the magnetic flux density.

Each of the fuel cells of the fuel cell stack has an air inlet through which air is supplied to the fuel cell, an air outlet from which the air is discharged, a hydrogen inlet through which a hydrogen gas is supplied to the fuel cell, and a hydrogen outlet from which the hydrogen gas is discharged. The magnetic sensor is located to be sensitive to a portion of the magnetic field appearing around one of the air inlet, the air outlet, the hydrogen inlet, and the hydrogen outlet.

The fuel cell control apparatus may further comprise a second magnetic sensor sensitive to a portion of the magnetic field appearing around another of the air inlet, the air outlet, the hydrogen inlet, and the hydrogen outlet to output a signal as a function a magnetic flux density of the portion of the magnetic field. The controller compares values of the signals outputted from the magnetic sensor and the second magnetic sensor with reference values predetermined on the condition that the fuel cell stack is operating normally to produce a required amount of electricity. When a difference between at least one of the values of the signals and a corresponding one of the reference values is found, the controller selects one of predetermined measures to eliminate the difference.

A current collector is disposed on one of ends of the fuel cell stack from which the electric current produced by the fuel cell stack is outputted.

According to the second aspect of the invention, there is provided a method of measuring a current distribution in a fuel cell stack which has a length made of a stack of a plurality of fuel cells each of which is made up of a first and a second separator and an assembly nipped between the first and second separators. The assembly includes an electrolyte, an air electrode affixed to a first surface of the electrolyte, and a fuel electrode affixed to a second surface of the electrolyte opposite the first surface. The method comprises (a) providing a magnetic sensor on a circumference of the fuel cell stack perpendicular to the length thereof to measure a magnetic field as generated by a flow of an electric current through the length of the fuel cell stack; (b) determining a current distribution in the fuel cell stack from the magnetic field measured by the magnetic sensor.

In the preferred mode of the invention, the magnetic sensor is disposed at a middle of the length of the fuel cell stack.

The method may further comprise providing additional magnetic sensors on the circumference of the fuel cell stack.

According to the third aspect of the invention, there is provided a fuel cell stack which comprise: (a) a plurality of fuel cells assembled into a stack, each of the fuel cells being made up of an electrolyte, an air electrode affixed to a first surface of the electrolyte, a fuel electrode affixed to a second surface of the electrolyte opposite the first surface, and separators with gas flow paths which nip an assembly of the electrolyte, the air electrode, and the fuel electrode therebetween; and (b) a magnetic sensor disposed on a circumference of the stack perpendicular to a length of the stack.

In the preferred mode of the invention, the magnetic sensor is disposed at the middle of the length of the stack.

The fuel cell stack may further comprise additional sensors disposed on the circumference of the stack.

The fuel cell stack may further comprise a current distribution determining circuit working to determine a current distribution in the stack using an output of the magnetic sensor produced as a function of a change in magnetic flux density.

According to the fourth aspect of the invention, there is provided a method of controlling an operation of a fuel cell stack which has a length made of a stack of a plurality of fuel cells each of which is made up of a first and a second separator and an assembly nipped between the first and second separators. The assembly includes an electrolyte, an air electrode affixed to a first surface of the electrolyte, a fuel electrode affixed to a second surface of the electrolyte opposite the first surface. The method comprises: (a) determining a distribution of amount of electricity generated by the fuel cell stack based on a magnetic field which is produced by an electric current flowing through the length of the fuel cell stack and measured by a magnetic sensor; and (b) controlling a supply of a gas to the fuel cell stack based on the distribution of amount of electricity.

In the preferred mode of the invention, the magnetic sensor is disposed at the middle of the length of the stack.

The method may further comprise providing additional sensors are disposed on the circumference of the stack.

The controlling step controls a flow rate of the gas supplied to one of the air electrode and the fuel electrode or humidity of the gas.

According to the fifth aspect of the invention, there is provided a method of measuring a current distribution in a fuel cell stack which has a length made of a stack of a plurality of fuel cells each of which is made up of a first and a second separator and an assembly nipped between the first and second separators. The assembly includes an electrolyte, an air electrode affixed to a first surface of the electrolyte, and a fuel electrode affixed to a second surface of the electrolyte opposite the first surface. A current collector is disposed on an end of the length of the fuel cell stack for outputting an electric current, as generated by the fuel cell stack, in a direction perpendicular to the length of the fuel cell stack. The method comprises: (a) providing a magnetic sensor on an end of the length of the fuel cell stack to measure a magnetic field as generated by a flow of an electric current through the current collector; and (b) determining a current distribution in the fuel cell stack from the magnetic field measured by the magnetic sensor.

In the preferred mode of the invention, the current collector is a current collector plate. The magnetic sensor works to measure the magnetic field around the current collector plate.

The method may further comprise providing additional magnetic sensors on the end of the length of the fuel cell stack.

According to the sixth aspect of the invention, there is provided a fuel cell stack which comprises: (a) a plurality of fuel cells assembled into a stack, each of the fuel cells being made up of an electrolyte, an air electrode affixed to a first surface of the electrolyte, a fuel electrode affixed to a second surface of the electrolyte opposite the first surface, and separators with gas flow paths which nip an assembly of the electrolyte, the air electrode, and the fuel electrode therebetween; (b) a current collector disposed on an end of the length of the fuel cell stack for outputting an electric current, as generated by the fuel cell stack; and (c) a magnetic sensor working to measure a magnetic filed produced around the current collector.

In the preferred mode of the invention, the current collector is a current collector plate. The magnetic sensor works to measure the magnetic field around the current collector plate.

The fuel cell stack may further comprise additional magnetic sensors on the end of the length of the fuel cell stack.

The fuel cell stack may further comprise a current distribution determining circuit working to determine a current distribution in the fuel cell stack using an output of the magnetic sensor produced as a function of a change in magnetic flux density of the magnetic field.

According to the seventh aspect of the invention, there is provided a method of controlling an operation of a fuel cell stack which has a length made of a stack of a plurality of fuel cells each of which is made up of a first and a second separator and an assembly nipped between the first and second separators. The assembly includes an electrolyte, an air electrode affixed to a first surface of the electrolyte, and a fuel electrode affixed to a second surface of the electrolyte opposite the first surface. A current collector being disposed on an end of the length of the fuel cell stack for outputting an electric current, as generated by the fuel cell stack, in a direction perpendicular to the length of the fuel cell stack. The method comprises: (a) determining a distribution of amount of electricity generated by the fuel cell stack based on a magnetic field which is produced by an electric current flowing through the current collector and measured by a magnetic sensor; and (b) controlling a supply of a gas to the fuel cell stack based on the distribution of amount of electricity.

In the preferred mode of the invention, the current collector is a current collector plate. The magnetic sensor works to measure the magnetic field around the current collector plate.

The method may further comprise providing additional magnetic sensors on the end of the length of the fuel cell stack.

The controlling step controls a flow rate of the gas supplied to one of the air electrode and the fuel electrode or humidity of the gas.

### DETAILED DESCRIPTION OF INVENTION

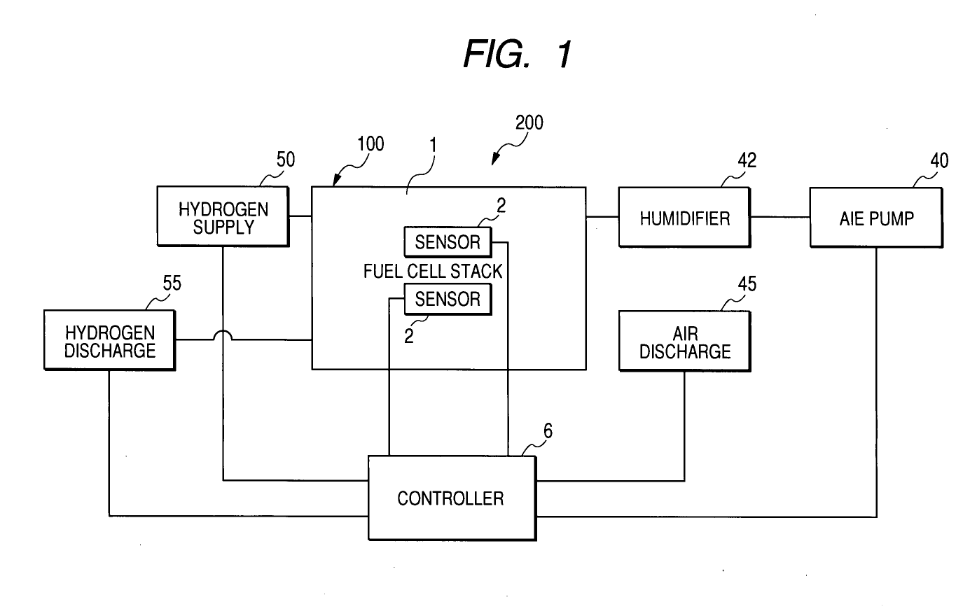

Referring to the drawings, wherein like reference numbers refer to like parts in several views, particularly to FIG. 1, there is shown a fuel cell system 200 according to the first embodiment of the invention which is designed to monitor a drop in ability of a fuel cell stack 1 to generate electricity, specify the cause thereof, and control an operation of the fuel cell stack 1 to eliminate such a cause in order to ensure the stability of the operation of the fuel cell stack 1.

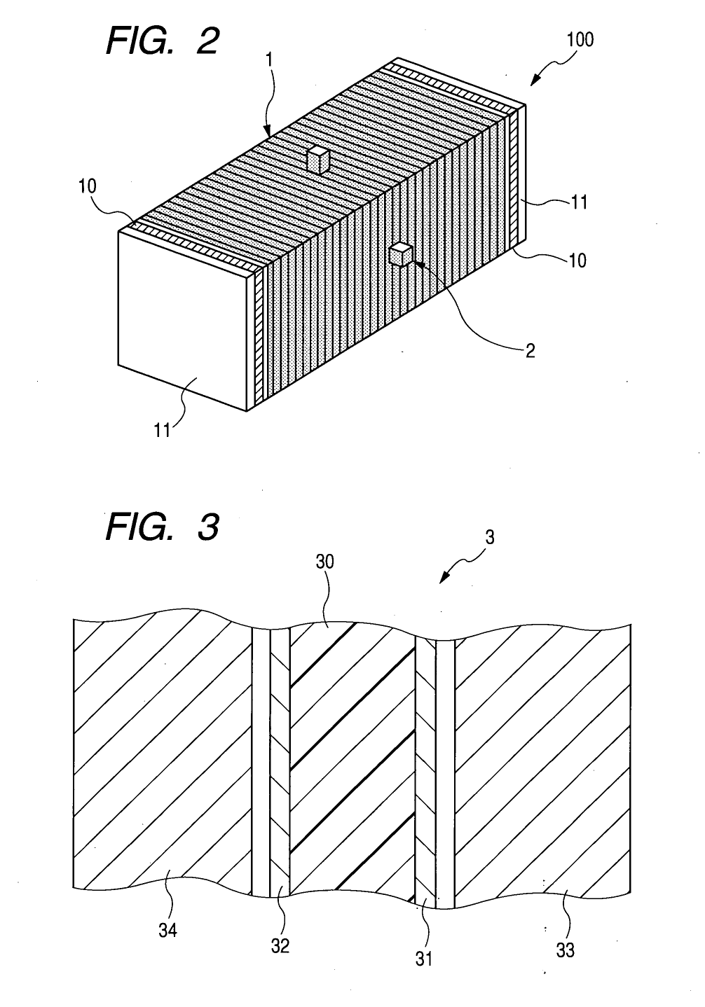

FIG. 2 shows a fuel cell apparatus 100 installed in the fuel cell system 200. The fuel cell apparatus 100 includes the fuel cell stack 1 and magnetic sensors 2.

The fuel cell stack 1 is made up of a plurality of fuel cells 3 is assembled into a stack. Each of the fuel cells 3 is, for example, a solid polymer fuel cell and, as clearly illustrated in FIG. 3, includes a membrane electrode assembly (MEA) and separators 33 and 34. The MEA consists of an electrolyte film 30, an air electrode (i.e., a cathode) 31, and a fuel electrode (i.e., an anode) 32. The air electrode 31 and the fuel electrode 32 are affixed to opposite surfaces of the electrolyte film 30. The MEA is nipped by the separators 33 and 34. The separators 33 and 34 will also be referred to below as an air-side separator and a fuel-side separator, respectively. The magnetic sensors 2 are installed on outer side surfaces of the fuel cell stack 1 and arrayed around the circumference of the fuel cell stack 1.

The magnetic sensors 2 are located in areas outside the electrolyte films 30 where the magnetic sensors 2 are sensitive to the magnetic field, as produced by the fuel cell stack 1, and may be disposed at a given distance from, on, or in the outer surfaces of the fuel cell stack 1. The magnetic sensors 2 are preferably located as close to an electricity-generating region 150, as will be discussed later in detail, of each of the cells 3 in which electrochemical reaction is taken place, as possible. The separators 33 and 34 are greater in size (i.e., area) than the electricity-generating region 150 of each of the cells 3

Each of the magnetic sensors 2 can be of any know type capable of measuring the magnetic field at a place where it is disposed. In the case where the fuel cell stack 1 is a typical polymer electrolyte fuel cell stack in which the area of the electricity-generating region 150 is 400 cm², and the current density is 1 A/cm², a maximum value of magnetic flux density is on the order of ±6×10⁻⁴ T (6 G). The magnetic sensors 2 may, therefore, be implemented by a Hall sensor, a magnetic resistance element, or a fluxgate sensor. One of these which is easy to handle for measuring the magnetic density on a plane expanding perpendicular to the thickness of the cells 3 is most suitable for use as the magnetic sensors 2.

Each of the separators 33 and 34 is made of a conductive material and serves as an electrode terminal plate. Specifically, the fuel-side separator 34 serves as a negative (−) electrode terminal, while the air-side separator 33 serves as a positive (+) electrode terminal. FIG. 3 illustrates the structure of each of the cells 3 schematically. The air-side and fuel-side separators 33 and 34, the air electrode 31, the fuel electrode 32, and the electrolyte film 30 are, in practice, much longer than the ones, as illustrated in FIG. 3, in the longitudinal direction of the drawing sheet. Each of the air-side and fuel-side separators 33 and 34 is, in practice, much greater in thickness than the electrolyte film 30. For instance, each of the air-side and fuel-side separators 33 and 34 has a thickness of 1 to 2 mm. Each of the MEAs includes the electrolyte film 30, gas-diffusion layers, and catalysts and has a total thickness of 0.5 mm. Each of the electrodes 31 and 32 includes the gas-diffusion layer which has a thickness of approximately 0.2 mm. The catalysts are disposed between the air electrode 31 and the electrolyte film 30 and between the fuel electrode 32 and the electrolyte film 30.

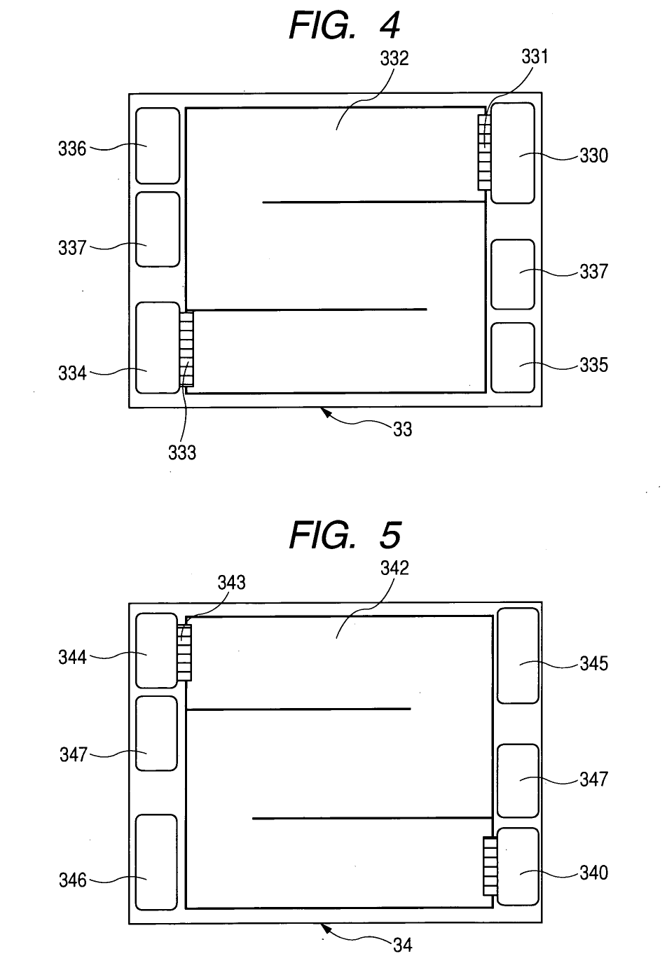

FIG. 4 shows the structure of each of the air-side separators 33. The air-side separator 33 has formed therein an air flow hole 330, an air inlet 331, an air outlet 333, and an air drain hole 334. The air flow hole 330 leads to an upstream end of the air flow groove 332 through the air inlet 331. The air flow groove 332 leads at a downstream end thereof to the air drain hole 334 through the air outlet 333. The air is supplied from an air supply path (not shown in FIG. 4) to the air flow hole 330, flows into the air flow groove 332 through the air inlet 331, and reaches the electricity-generating region 150 of one of the cells 3. The air then flows out of the air flow groove 332 to the air drain hole 334 through the air outlet 333 and is discharged to an air discharge path (not shown in FIG. 4). The air supply path leads to an air pump 40 through a humidifier 42, as illustrated in FIG. 1. The air discharge path leads to an air discharged device 45.

The air-side separator 33 also includes a hydrogen flow hole 335 and a hydrogen drain hole 336. The hydrogen flow hole 335 leads to a hydrogen supply path (not shown). The hydrogen drain hole 336 to a hydrogen discharge path (not shown). The hydrogen supply path and the hydrogen discharge path lead to a hydrogen supply device 50 and a hydrogen discharged device 55, as illustrated in FIG. 1.

FIG. 5 shows the structure of each of the fuel-side separators 34. The fuel-side separator 34 has formed therein a hydrogen flow hole 340, hydrogen inlet 342, a hydrogen outlet 343, and a hydrogen drain hole 344. The hydrogen flow hole 340 communicates with the hydrogen flow hole 335 of the air-side separator 33 to define a hydrogen inlet path leading to the hydrogen supply path. The hydrogen drain hole 344 communicates with the hydrogen drain hole 336 of the air-side separator 33 to define a hydrogen outlet path leading to the hydrogen discharge path. The hydrogen flow hole 340 leads to an upstream end of the hydrogen flow groove 342 through the hydrogen inlet 341. The hydrogen flow groove 342 leads at a downstream end thereof to the hydrogen drain hole 344 through the hydrogen outlet 343. The hydrogen gas is supplied from the hydrogen supply common path to the hydrogen flow hole 340, flows into the hydrogen flow groove 342 through the hydrogen inlet 341, and reaches the electricity-generating region 150 of one of the cells 3. The hydrogen gas then flows out of the hydrogen flow groove 342 to the hydrogen drain hole 344 through the hydrogen outlet 343 and is discharged to the hydrogen discharge common path.

The fuel-side separator 34 also includes an air flow hole 345 and an air drain hole 346. The air flow hole 345 communicates with the air flow hole 330 of the air-side separator 33 to define an air inlet path leading to the air supply path. The air drain hole 346 communicates with the air drain hole 334 of the air-side separator 33 to define an air outlet path communicating with the air discharge path.

The air-side separator 33 and the fuel-side separator 34 have formed therein a coolant flow hole 337 and a coolant flow hole 347 which define a coolant flow path through which a coolant is recirculated.

The fuel cell stack 1 is, for example, made up of the fifty (50) cells 3 laid to overlap each other to define the length of the fuel cell stack 1 and the separators 33 and 34 nipping the cells 3 therebetween. The separators 33 and 34, the electrodes 31 and 32, and the electrolyte film 30 are assembled into a unit (i.e., the fuel cell 3). All of the separators 33 and 34 of the fuel cell stack 1 are, in practice, arrayed in a face-to-face abutment with each other to define the air inlet and outlet paths and the hydrogen inlet and outlet paths.

Note that the air-side separator 33 and the fuel-side separator 34 are shown in FIGS. 4 and 5 as viewed from the left side of the fuel cell 3 of FIG. 3 for the brevity of illustration. The air-side separator 33 and the fuel-side separator 34 can be of any known type and do not form major parts of the invention. Explanation thereof in more detail will, therefore, be omitted here. For example, Japanese Patent First Publication No. 11-339828 discloses separators which may be employed in the fuel cell stack 1, the disclosure of which is incorporated herein by reference.

Referring back to FIG. 2, the fuel cell apparatus 100 also includes current collector plates 10 affixed to ends of the fuel cell stack 1. The current collector plates 10 are each made of a square metal plate and have terminals (not shown) extending outwardly in a direction perpendicular to the lengthwise direction of the fuel cell stack 1. The terminals of the current collector plates 10 also lead to the electrodes 31 and 32 of outermost two of the fuel cells 3, respectively. In assembling, the fuel cell stack 1 is compressed from outside the current collector plates 10 by press plates 11 through insulating plates in the lengthwise direction thereof and held as it is to ensure the airtight sealing of the fuel cell stack 1 and enhance the adhesion among the fuel cells 3.

The fuel cell stack 1 has a given length and is substantially square in cross section. The magnetic sensors 2 are installed, one on the center of each of four side surfaces of the fuel cell stack 1 in the lengthwise direction thereof.

Referring back to FIG. 1, the fuel cell system also includes the air pump 40, the humidifier 42, the air discharge device 45 equipped with a back pressure valve, the hydrogen supply device 50, the hydrogen discharge device 55 equipped with a back pressure valve, and the controller 6. The air pump 40 may be equipped with a pressure regulator valve and works to supply air to the humidifier 42. The humidifier 42 humidifies the air and feeds it to each of the fuel cells 3 through the air supply common path. The air discharge device 45 connects with each of the fuel cells 3 through the air discharge common path. The hydrogen supply device 50 includes a pump or a pressure regulator valve and a humidifier and works to supply the hydrogen gas from a hydrogen tank (not shown) to each of the fuel cells 3 through the hydrogen supply common path. The hydrogen discharge device 55 connects with the hydrogen discharge common path. The coolant flow path connects with coolant supply and discharge devices (not shown). The hydrogen supply device 50 is equipped with a hydrogen flow rate regulator and a moisture flow rate regulator. The air pump 40 is equipped with an air flow rate regulator. The humidifier 42 is equipped with a moisture flow rate regulator.

The controller 6 connects with the magnetic sensors 2, the air pump 40, the humidifier 42, the air discharge device 45, the hydrogen supply device 50, and the hydrogen discharge device 55. The controller 6 works to control operations of the hydrogen flow rate regulator of the hydrogen supply device 50, the air flow rate regulator of the air pump 40, and the moisture flow rate regulators of the hydrogen supply device 50 and the humidifier 42 to regulate the flow rate of the hydrogen gas and the air and the quantity of moisture contained in the hydrogen gas and air, selectively. Specifically, the controller 6 works to analyze a change in magnetic flux density, as sensed by the magnetic sensor 2 to determine the current distribution in the fuel cell stack 1, find a factor (e.g., a drop in performance of the fuel cell stack 1) resulting in a local variation or nonuniformity of the current distribution, and regulate the flow rate of the hydrogen gas or the air or the quantity of moisture contained in the hydrogen gas or the air which is to be supplied to the fuel cell stack 1 to eliminate the nonuniformity of the current distribution.

The principle of finding the current distribution in the fuel cell stack 1 using the magnetic sensors 2 will be described below.

The magnetic sensors 2 each work to produce an output as a function of the magnetic field (i.e., the magnetic flux density) created by a flow of electric current through the fuel cell stack 1 in the lengthwise direction thereof (i.e., the widthwise direction of each of the cells 3).

It is generally noted that the flow of electric current i (A) through a conductor of an infinite length will cause the magnetic flux density B (Wb/m²), as expressed in Eq. (1) below, to appear at a distance r(m) from the conductor (i.e., the right-handed screw rule).

B=2×10⁻⁷(i/r) (1)

When the fuel cell stack 1 is activated, the electric current, as produced by each of the fuel cells 3, flows through the fuel cell stack 1 in the lengthwise direction thereof. This will cause the magnetic field to be produced in the circumferential direction of the fuel cell stack 1. The cells 3 of the fuel cell stack 1 each have a given transverse section. If the transverse section is broken down into a plurality of discrete minute areas, the magnetic field produced in the fuel cell stack 1 may be considered to be given by the sum of magnetic fields arising from flows of electric current through the respective minute areas. If no current flows through (i.e., no electricity is produced in) one or some of the minute areas meaning that the ability to generate the electrical energy drops (i.e., the current flowing through one or some of the minute area decreases), it will result in a change in the magnetic flux density developed in the circumferential direction of the fuel cell stack 1. The controller 6 monitors such a change using outputs of the magnetic sensors 2 to determine a change in the current distribution in the fuel cell stack 1.

In general, assuming that the current is flowing in a finite area, the distribution of magnetic flux density over the finite area may be determined by integrating the magnetic flux, as produced by the flow of the current. The magnetic flux density of the magnetic field, as developed as a function of the current distribution within the fuel cell stack 1, will be explained below with reference to FIGS. 6 to 9 on the condition that the fuel cell stack 1 (i.e., each of the cells 3) and an object (not shown) such as a stack casing or stack holder are identical in magnetic permeability with air.

It is assumed that each of the cells 3, as illustrated in FIG. 6, has a square electricity-generable region 130. The electricity-generable region 130 is the region where the electrochemical reaction is developed which is, in practice, an area of the cell 3 made up of the electrolyte film 30, the air electrode 31, and the fuel electrode 32 to which the hydrogen and oxygen gasses are supplied.

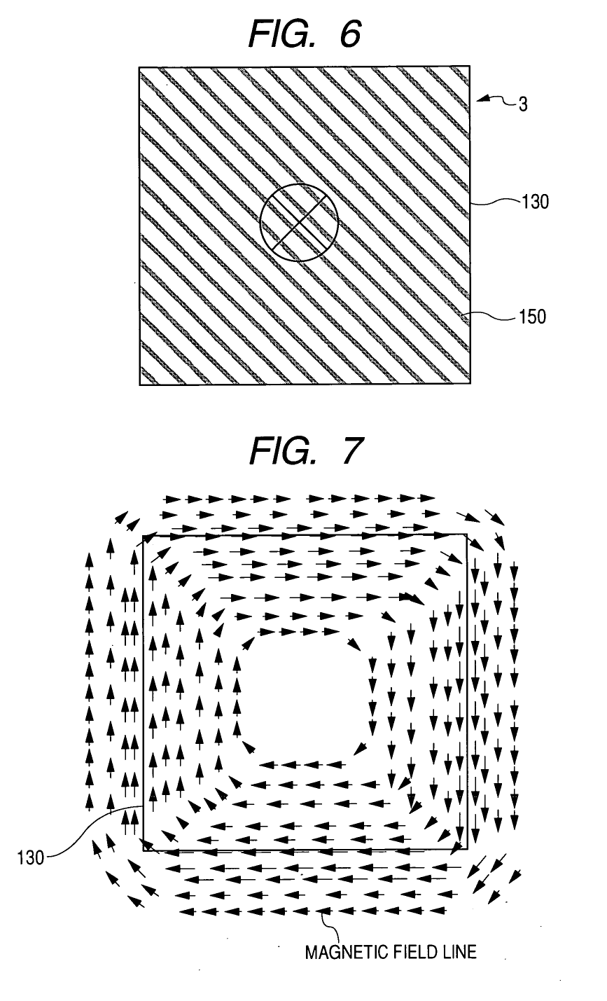

In the cell 3 illustrated in FIG. 6, the electricity is produced over the whole of the electricity-generable region 130 (i.e., a hatched area). When the electrochemical reaction is taken place, so that the current flows perpendicular to the drawing sheet from the front thereof, it will result in production of the magnetic field, as indicated by magnetic field lines oriented in the clockwise direction. The magnetic flux density in the magnetic field, as can be seen from FIG. 7, has the distribution where the magnetic flux density increases around the perimeter of the electricity-generable region 130, while it decreases around the center.

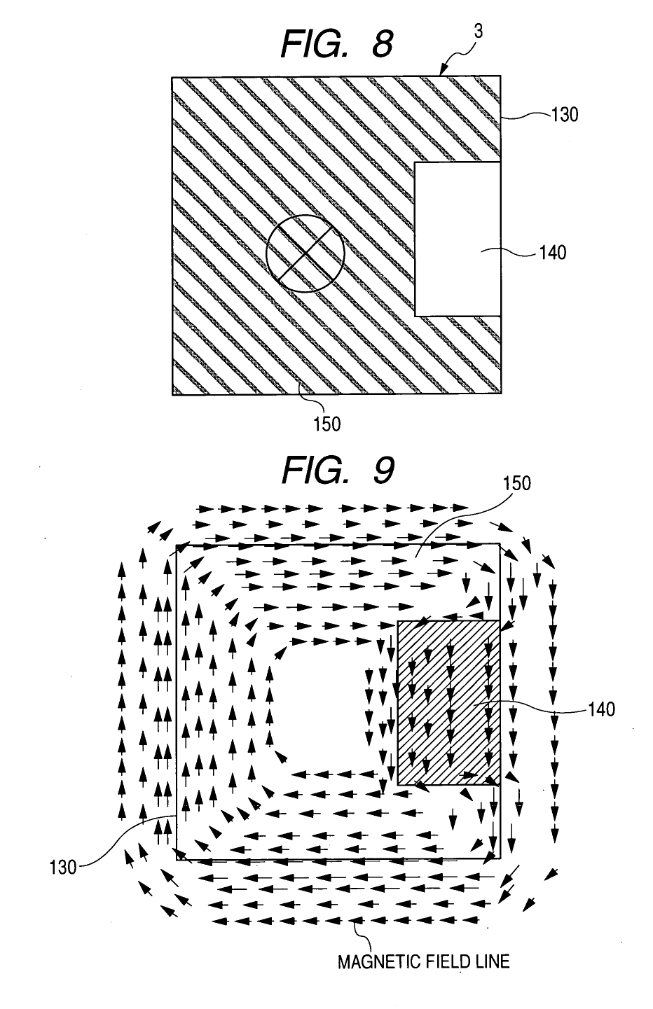

If no electrochemical reaction, as indicated by a white rectangle 140 in FIG. 8, is partially developed in the electricity-generable region 130, it will cause the magnetic field to be produced, as indicated by the magnetic field lines in FIG. 9. Specifically, the magnetic field lines extend in the clockwise direction along the perimeter of the electricity-generable region 130 and an interface between the electrochemical reaction disabled area 140 and the electricity-generable region 130 (i.e., the perimeter of the electrochemical reaction disabled area 140). The magnetic field around the outside perimeter of the electrochemical reaction disabled area 140 (i.e., a portion of the outer periphery of the electricity-generable region 130 coinciding with the outer periphery of the electrochemical reaction disabled area 140) is smaller in magnetic flux density than that around the outer perimeter of the electricity-generating region 150 (i.e., a portion of the outer periphery of the electricity-generable region 130 coinciding with the outer periphery of the electricity-generating region 150). Additionally, the magnetic flux density greatly decreases around the center of the electricity-generable region 130.

A comparison between the cells 3 of FIGS. 7 and 9 shows that the magnetic flux density of a portion of the magnetic filed around the perimeter of the electricity-generating region 150 is different from that around the outside portion of the perimeter of the electrochemical reaction disabled area 140, thereby enabling the presence of the electrochemical reaction disabled area 140 to be found by measuring the magnetic flux density around the perimeter of the electricity-generable region 130 to detect a change in the current distribution in the fuel cell stack 1 from one when the fuel cell stack 1 is operating properly.

If one of the cells 3 of the fuel cell stack 1 partially drops in the ability to generate the electricity for some reason, so that the electrochemical reaction disabled area 140 appears at the one, it will result in a lack of flow of the current through areas of the other cells 3 spatially coinciding with the electrochemical reaction disabled area 140 of the one. The presence of the electrochemical reaction disabled area 140 of one of the cells 3 may, therefore, be found by measuring the magnetic flux density around another of the cells 3.

The controller 6 is designed to measure the magnetic flux density around the perimeter of the electricity-generating region 150 of one of the cells 3 using the magnetic sensors 2 to find a change in the current distribution in the fuel cell stack 1 from one when the fuel cell stack 1 is operating normally and determine whether the electrical energy generation disabled area (i.e., the electrochemical reaction disabled area 140) exists or not. It is advisable that the magnetic sensors 2 be located at the middle of the length of the fuel cell stack 1. This is for the following reasons:

The fuel cell stack 1 is so designed that the current flows through the length of the fuel cell stack 1 and turns in the current collector plates 10 in a direction perpendicular to the length of the fuel cell stack 1.

Therefore, if the magnetic sensors 2 are located close to one of the current collector plates 10, it may cause electrical noises arising from the magnetic field produced by the current flowing through the current collector plate 10 to be added to outputs of the magnetic sensors 2, which leads to an error in determining the current distribution in the fuel cell stack 1.

It is also advisable that at least one of the magnetic sensors 2 be located farther from the fuel cell stack 1 than the others. Usually, an error of the order of ±0.3×10⁻⁴ T (0.3 G) arises in determining the current distribution due to the earth magnetism. Such an error may be eliminated by disposing one of the magnetic sensors 2 far from the fuel cell stack 1 to measure only the earth magnetism and correcting outputs from the other sensors 2 so as to compensate for an error component contained therein arising from the earth magnetism.

It is further advisable that the magnetic sensors 2 be used each of which includes two sensor elements: one sensitive to a vertical magnetic flux oriented in a vertical direction (y-direction) on a two-dimensional plane extending perpendicular to the length of the fuel cell stack 1, and the other sensitive to a lateral magnetic flux oriented in a lateral direction (x-direction) on the plane.

Referring back to FIG. 1, the fuel cell system 200 is, as described above, designed to find a change in the current distribution in the fuel cell stack 1 using outputs of the magnetic sensors 2. The structural material thereof is preferably any low permeability material, such as austenitic stainless steel, which does not disturb the magnetic field around the fuel cell stack 1. When cold-worked, the austenitic stainless steel usually undergoes a rise in permeability. This is preferably minimized by annealing the steel.

The fuel cell system 200 works to determine the current distribution in the fuel cell stack 1 and control the flow rate of the hydrogen or oxygen gas or the quantity of moisture contained in the hydrogen or oxygen gas to maintain the ability of the fuel cell stack 1 to generate the electrical energy at a desired level.

In operation, the fuel cell system 200 supplies air (i.e., oxygen gas) to the air electrodes 31 of the cells 3 and the hydrogen gas to the fuel electrodes 32 of the cells 3 and induces the electrochemical reaction between the hydrogen and oxygen in each of the cells 3 to generate the electrical energy. The cells 3 are implemented by solid polymer fuel cells and use moisture as a medium for proton conduction. The hydrogen gas to be supplied to the cells 3 is, thus, humidified by the humidifier installed in the hydrogen supply device 50. An excess of moisture, however, disturbs the power generation in the cells 3, thus resulting in a drop in power of the cells 3 to generate the electricity. One of factors resulting in the drop in ability to generate the electricity partially occurring in the cells 3 is, therefore, thought of as being caused by the moisture. Such a drop is noted to occur mainly at portions of each of the cells 3 near the hydrogen inlet 341 of the fuel-side separator 34 into which the humidified hydrogen gas enters and near the air outlet 333 of the air-side separator 33 at which the moisture produced by the reaction at the air electrode 31 stays. The location of a portion of the cell 3 where the ability to generate the electricity has dropped may, therefore, be found by monitoring outputs of the magnetic sensors 2, comparing them with those derived by tests performed on the condition that the fuel cell stack 1 is operating properly to generate an expected amount of electricity, select one of the magnetic sensors 2 indicating an undesirable change in the magnetic flux density, and specifying one of some possible causes as resulting in the drop in the ability to generate the electricity. The controller 6 of the fuel cell control system 200 regulates the supply of the hydrogen or oxygen (air) gas or the moisture contained therein to the fuel cell stack 1 to minimize or eliminate the electricity generating ability drop.

The operation of the fuel cell system 200 will be described below in more detail.

The air supply device 40 supplies the air to the humidifier 42. The humidifier 42 humidifies the air and feeds it to the air electrodes 31 of the fuel cells 3 through the air flow hole 330 of the air-side separators 33. The hydrogen supply device 50 humidifies the hydrogen gas and feeds it to the fuel electrodes 32 of the fuel cells 3 through the hydrogen flow hole 340 of the hydrogen-side separators 34. This results in the generation of the electricity in each of the fuel cells 3. When no defects occur in any of the fuel cells 3, the electrical energy or current will be produced uniformly over the whole of the electricity-generating region 150 of each of the fuel cells 3, so that the distribution of current flowing in the lengthwise direction of the fuel cell stack 1 will be uniform.

The inventors of this application have experimentally found that the drop in ability of the fuel cell stack 1 to generate the electricity generally rises from any of six factors: 1) a lack of the hydrogen gas, 2) a lack of the air, 3) a lack in humidifying the hydrogen gas, 4) an excess of moisture in the hydrogen gas, 5) a lack in humidifying the air, and 6) an excess of moisture in the air. The first factor results in a decrease in current near the hydrogen outlet 343 of the fuel-side separator 34. The second factor results in a decrease in current near the air outlet 333 of the air-side separator 33. The third factor results in a decrease in current near the hydrogen inlet 341 of the fuel-side separator 34. The fourth factor results in a decrease in current near the hydrogen inlet 341 of the fuel-side separator 34. The fifth factor results in a decrease in current near the air inlet 331. The sixth factor results in a decrease in current near the air outlet 333 of the air-side separator 33.

The second and sixth factors bring about the same result and may be discriminated from each other by analyzing a history on the operation of the fuel cell stack 1 or the temperature of the cooling water circulating the fuel cell stack 1. Specifically, when the analysis of the operating history of the fuel cell stack 1 shows that a large amount of electricity has been produced, the decrease in current near the air outlet 333 of the air-side separator 33 is determined as having arisen from the excess of moisture in the air supplied to the fuel cell stack 1. Conversely, when a small amount of electricity is found to have been produced, the decrease in current near the air outlet 333 of the air-side separator is determined as having arisen from the lack of the air supplied to the fuel cell stack 1. The operating history is preferably recorded in a memory installed in the controller 6. When the temperature of the cooling water is found to be high, it means that a large amount of electricity has been produced. The decrease in current near the air outlet 333 of the air-side separator 33 is, thus, determined as having arisen from the excess of moisture in the air supplied to the fuel cell stack 1. Conversely, when the temperature of the cooing water is found to be low, it means that a small amount of electricity has been produced. The decrease in current near the air outlet 333 of the air-side separator 33 is, thus, determined as having arisen from the lack of the air supplied to the fuel cell stack 1. The temperature of the cooling water may be measured by reading an output of a water temperature sensor typically installed in a cooling water recirculation system.

The third and fourth factors bring about the same result and may be discriminated from each other, like the above, by analyzing a history on the operation of the fuel cell stack 1 or the temperature of the cooling water circulating the fuel cell stack 1. Specifically, when the analysis of the operating history of the fuel cell stack 1 shows that a large amount of electricity has been produced, the drop in ability to generate the electricity near the hydrogen inlet 341 is determined as having arisen from the excess of moisture in the hydrogen gas supplied to the fuel cell stack 1. Conversely, when a small amount of electricity is found to have been produced, the drop in ability to generate the electricity near the hydrogen inlet 341 is determined as having arisen from the lack of the moisture in the hydrogen gas supplied to the fuel cell stack 1. When the temperature of the cooling water is found to be high, it means that a large amount of electricity has been produced. The drop in ability to generate the electricity near the hydrogen inlet 341 is determined as having arisen from the excess of moisture in the hydrogen gas supplied to the fuel cell stack 1. Conversely, when the temperature of the cooling water is found to be low, it means that a small amount of electricity has been produced. The drop in ability to generate the electricity near the hydrogen inlet 341 is determined as having arisen from the lack of the moisture in the hydrogen gas supplied to the fuel cell stack 1.

The first factor is eliminated by increasing a supply of the hydrogen gas to the fuel cell stack 1. This is achieved by controlling the flow rate regulator of the hydrogen supplying device 50 to increase the flow rate of the hydrogen gas.

The second factor is eliminated by increasing a supply of the air to the fuel cell stack 1. This is achieved by controlling the flow rate regulator of the air pump 40 to increase the flow rate of the air.

The third factor is eliminated by increasing the amount of humidification of the hydrogen gas. This is achieved by controlling the moisture flow rate regulator of the humidifier of the hydrogen supply device 50 to increase the amount of moisture to be added to the hydrogen gas.

The fourth factor is eliminated by decreasing the amount of humidification of the hydrogen gas. This is achieved by controlling the moisture flow rate regulator of the humidifier of the hydrogen supply device 50 to decrease the amount of moisture to be added to the hydrogen gas.

The fifth factor is eliminated by increasing the amount of humidification of the air. This is achieved by controlling the moisture flow rate regulator of the humidifier 42 to increase the amount of moisture to be added to the air.

The sixth factor is eliminated by opening the back pressure valve of the air discharge device 45 temporarily to drain the water from the air discharge path, turning off the humidifier 42 to stop humidifying the air, and/or increasing the temperature of the cooling water. The third is achieved by controlling an operation of a radiator typically installed in the cooling water recirculation system, for example, by decreasing the speed of a fan of the radiator.

By way of example, the fourth and six factors and how to eliminate them will be discussed below in detail in the case where the four magnetic sensors 2 are affixed to or embedded in portions of the air-side and hydrogen-side separators 33 and 34 close to the air inlet 331, the air outlet 333, the hydrogen inlet 341, and the hydrogen outlet 343.

The fuel electrode 32 of each of the fuel cells 3 is, as described above, supplied with the humidified hydrogen gas through the hydrogen inlet path extending in the separators 33 and 34. The moisture contained in the hydrogen gas works as a medium for transporting the protons. As the hydrogen gas travels through the hydrogen flow groove 342 of the fuel-side separator 34 of each of the fuel cells 3, the moisture is, thus, consumed as the medium for the proton transport. This causes the concentration of moisture contained in the hydrogen gas flowing through the hydrogen flow groove 342 to decrease from the hydrogen inlet 341 to the hydrogen outlet 342.

When the amount of moisture in the hydrogen gas reaching the fuel electrode 34 increases, that is, when the amount of moisture near the hydrogen inlet 341 of the hydrogen flow groove 342 increases undesirably, it will be a disturbance in development of the electrochemical reaction at a portion of the fuel electrode 34 near the hydrogen inlet 341, so that the ability to generate the electricity drops at that portion. This drop will result in a variation in amount of the electricity to be generated in the electricity-generating region 150 of the fuel cell 3, thus leading to a variation in distribution of the current flowing in the lengthwise direction of the fuel cell stack 1 which is detected by one of the magnetic sensors 2 as a variation in the magnetic flux density near the hydrogen inlet 341 of the fuel-side separator 34.

The controller 6 analyzes outputs of all of the magnetic sensors 2, compares them with reference sensor outputs found experimentally as being produced by the magnetic sensors 2 on the condition that the fuel cell stack 1 is operating properly at the same electrical load as now to select one of the outputs of the magnetic sensor 2 which has a change from a corresponding one the reference sensor outputs, and specifies the cause and location of the variation in the current distribution (i.e., the magnetic flux density) in the fuel cell stack 1, that is, determines that the drop in the ability to generate the electricity has arisen from the excess of moisture contained in the hydrogen gas. The controller 6 then controls the moisture flow rate regulator of the hydrogen supply device 50 to decrease the amount of moisture to be added to the hydrogen gas supplied to the fuel cells 3 until the output of the one of the magnetic sensors 2 agrees with the corresponding one of the reference sensor outputs. This maintains the total ability of the fuel cell stack 1 to generate the electricity at a desired level.

Note that a lack of moisture in the hydrogen gas supplied to the fuel cell stack 1 may be determined by the power of the fuel cell stack 1 to generate the electricity and the amount of moisture in the hydrogen gas discharged to the hydrogen discharge device 55.

The moisture produced by the electrochemical reaction at the air electrode 31 of each of the fuel cells 3 usually diffuses within the electrolyte film 30 and reaches the fuel cell 33 to serve to draw hydrogen ions (H⁺) to the air electrode 31. This may result in a lack of the amount of moisture near the air outlet 333 of the air-side separator 33, thus leading to a drop in the ability to generate electricity.

When the amount of moisture passing the electrolyte film 30 increases, that is, when the amount of moisture in the air flow groove 332 increases undesirably, it will cause the moisture to penetrate into the electrolyte film 30 and reach the fuel electrode 34, thus resulting in a lack in development of the electrochemical reaction at a portion of the air electrode 33 near the air outlet 333 of the air flow groove 332 of the air-side separator 33, so that the ability to generate electricity drops at that portion. This drop will result in a variation in amount of electricity to be generated in the electricity-generating region 150 of the fuel cell 3, thus leading to a variation in distribution of the current flowing in the lengthwise direction of the fuel cell stack 1 which is detected by one of the magnetic sensors 2 as a variation in the magnetic field around the circumference of the fuel cell 3.

The controller 6 analyzes outputs of all of the magnetic sensors 2, compares them with the reference sensor outputs, as described above, to select one of the outputs of the magnetic sensor 2 which has a change from a corresponding one the reference sensor outputs, and specifies the cause and location resulting in the variation in the current distribution (i.e., the magnetic flux density) in the fuel cell stack 1, that is, determines that the drop in the ability to generate electricity has arisen from the excess of moisture in the air flow groove 332. The controller 6 then controls, for example, the moisture flow rate regulators of the humidifier 42 to decrease the amount of moisture in the air flow groove 332 until the output of the one of the magnetic sensors 2 agrees with the corresponding one of the reference sensor outputs.

The fuel cell apparatus 100 may be designed to use the single magnetic sensor 2. The drop in power generating ability of the fuel cell stack 1 is, as described above, thought of as arising from any of the six factors: 1) a lack of the hydrogen gas, 2) a lack of the air, 3) a lack in humidifying the hydrogen gas, 4) an excess of moisture in the hydrogen gas, 5) a lack in humidifying the air, and 6) an excess of moisture in the air. The first factor is found to have the highest possibility to bring about the drop in power generating ability of the fuel cell stack 1. The magnetic sensor 2 may, therefore, be installed only on or in a portion of the fuel-side separator 34 near the hydrogen outlet 343 to measure a variation in magnetic flux density around a portion of the electricity-generable region 130 of one of the fuel cells 3 near the hydrogen outlet 343. The controller 6 compares an output of the magnetic sensor 2 with a reference sensor output as found experimentally and determines that the power generating ability of the fuel cell stack 1 has dropped due to the lack of the hydrogen gas when there is a difference between the output of the magnetic sensor 2 and the reference sensor output.

The fuel cell apparatus 100 may also be designed to use the two or three magnetic sensors 2 to detect a drop in the power generating ability of the fuel cell stack 1. The third factor (i.e., the lack in humidifying the hydrogen gas) is found to have a lower possibility to bring about the drop in the power generating ability of the fuel cell stack 1. The fourth factor (i.e., the excess of moisture in the hydrogen gas) is found to have the lowest possibility. The three magnetic sensors 2 may, therefore, be installed on or in a portion of the fuel-side separator 34 near the hydrogen outlet 343 and portions of the air-side separator 33 near the air inlet 331 and the air outlet 333, respectively, to omit the detection of a decrease in current which is to occur near the hydrogen inlet 341. The controller 6 compares each of outputs of the magnetic sensors 2 with a corresponding one of reference sensor outputs as found experimentally, specifies the cause and location resulting in the power generating ability drop of the fuel cell stack 1, and takes one or some of the measures, as described above, to recover the total amount of electricity produced by the fuel cell stack 1.

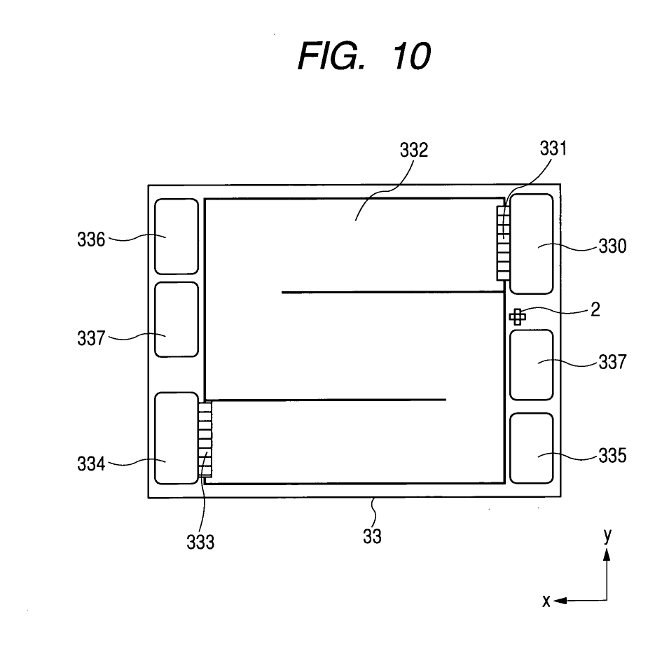

FIG. 10 shows a modification of the air-side separator 33 which has the magnetic sensor 2 affixed to or embedded in a wall thereof facing the air electrode 31. The magnetic sensor 2 is illustrated as being located near the air inlet 331 to measure a change in the magnetic flux density arising from a drop in the ability to generate the electricity near the air inlet 331 (i.e., the fifth factor, as described above), but may alternatively be installed near the air outlet 333 to specify the second or sixth factors. Of course, the two magnetic sensors 2 may be installed near the air inlet 331 and the air outlet 333. The magnetic sensor 2, as illustrated, is made up of two sensor elements: one sensitive to a magnetic flux flowing in a y-direction on a plane extending perpendicular to the width of the separator 33, and the other sensitive to a magnetic flux flowing in an x-direction.

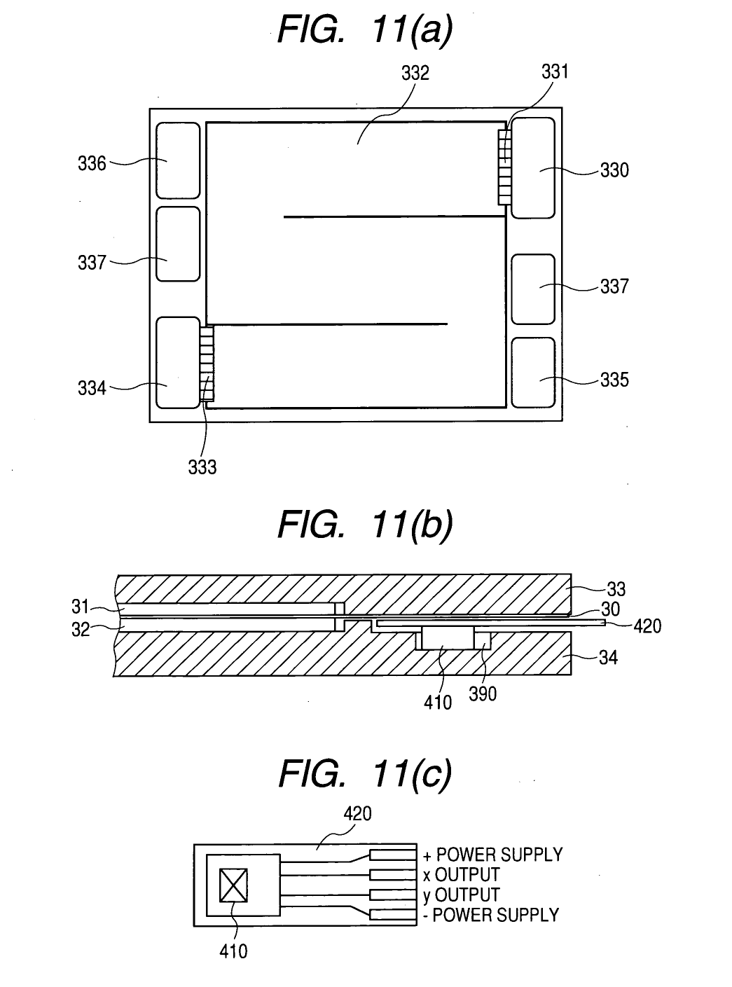

FIG. 11(a) shows another modification of the air-side separator 33 which has the magnetic sensor 2 affixed thereto. The magnetic sensor 2 is, as clearly shown in FIG. 11(b), disposed within a recess 390 formed in the fuel-side separator 34. The separators 33 and 34 are made of carbon. The magnetic sensor 2 is designed to have sensitivities in two-dimensional directions (i.e., x and y directions). The magnetic sensor 2 is made of a chip on which a magnetic resistance element 410 and an analog processor are fabricated. The chip is mounted on a 0.3 mm-thick polyimide substrate 420. A plus power terminal, an x output terminal, a y output terminal, and a minus power terminal are bonded to the substrate 420. The terminals are connected to the controller 6 through a connector (not shown). The substrate 420 is coated with an insulating material for electrically isolating the magnetic sensor 2 from the separators 33 and 34. The substrate 420 is attached to the separator 33 using, for example, an epoxy resin adhesive. The separators 33 and 34 may alternatively be made of a metallic material such as a stainless steel.

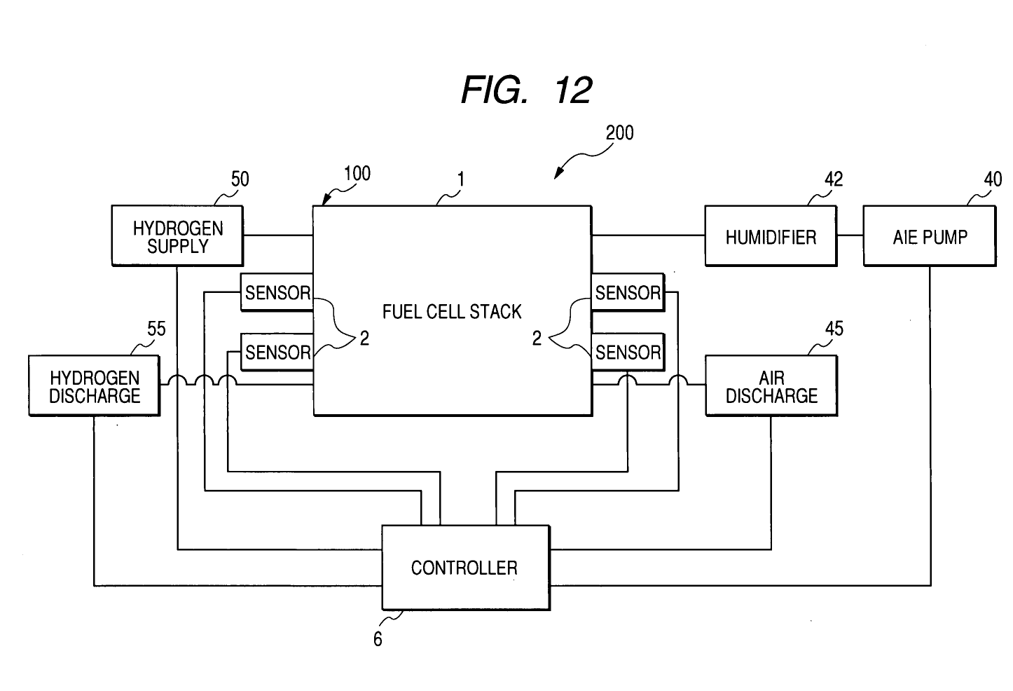

FIG. 12 shows the fuel cell system 200 according to the second embodiment of the invention which is different from the one of FIG. 1 in that the magnetic sensors 2 are affixed to ends of the fuel cell stack 1 to monitor a drop in the ability to generate the electricity. The same reference numbers as employed in the first embodiment will refer to the same parts, and explanation thereof in detail will be omitted here.

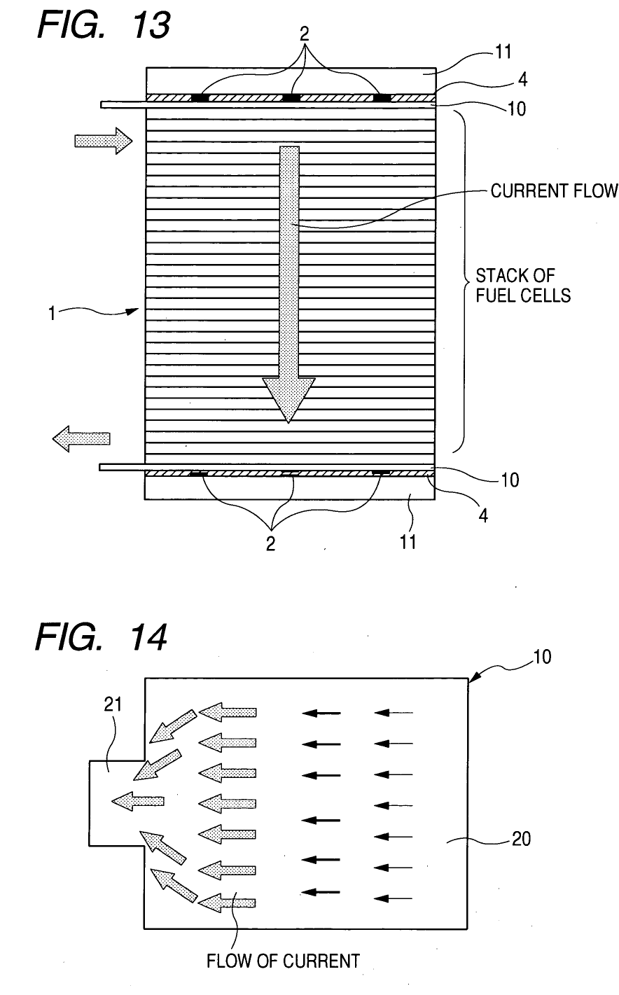

FIG. 13 shows the fuel cell apparatus 100 which includes the fuel cell stack 1, the current collector plates 10, the insulating plates 4, and the press plates 11. The current collector plates 10 are attached to the ends of the fuel cell stack 1. The insulating plates 4 are attached to the current collector plates 10. The press plates 11 hold an assembly of the fuel cell stack 1, the current collector plates 10, and the insulating plates 4 tightly to ensure the airtight sealing of the fuel cell stack 1 and enhance the adhesion among the fuel cells 3.

Each of the current collector plates 10, as illustrated in FIG. 14, made up of a plate body 20 and a current output terminal 21. The plate bodies 20 are identical in profile or area with the ends of the fuel cell stack 1. The current output terminals 21 extend laterally from sides of the plate bodies 20.

The electric current, as generated by the fuel cells 3, flows through, as indicated by an arrow in FIG. 13, the length of the fuel cell stack 1 and reaches the plate body 20 of the current collector plate 10. Upon reaching the plate body 20, the current turns 90° and travels to the current output terminal 21. As the current moves toward the current output terminal 21, the current density thereof increases. In FIG. 14, the width of arrows represents the magnitude of the current density on the current collector plate 10. Arrows arrayed vertically on the rightmost side of FIG. 14 represent flows of current which are produced by rightmost portions of the fuel cells 3, as viewed in FIG. 13, and appear at an area of the plate body 20 of the current collector plate 10 farthest from the current output terminal 21.

At an area of the plate body 20 of the current collector plate 10 on the left side of the rightmost array of arrows, flows of current which are produced by portions of the fuel cells 3 on the left side of the rightmost portions of the fuel cells 3, as viewed in FIG. 13, appear and join the right flows of current. In this way, the current density increases from the right end of the plate body 20, as viewed in FIG. 14, toward the current output terminal 21.

When each of the fuel cells 3 generates the electricity uniformly over the electricity-generable region 130, the current density on the plate body 20 of the current collector plate 10 increases as approaching the current output terminal 21 substantially as a function of a distance to the current output terminal 21.

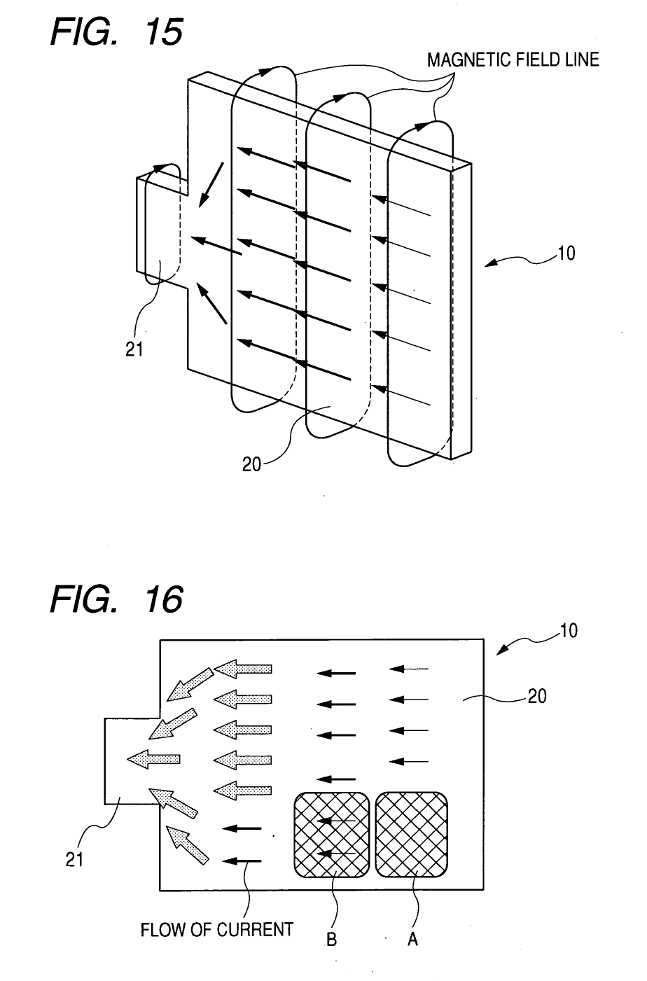

The flows of current through the current collector plate 10 will result in, as clearly shown in FIG. 15, production of the magnetic field around the current collector plate 10. Specifically, the magnetic field is produced, as illustrated in FIG. 15, which is represented by magnetic field lines extending around a cross section of the current collector plate 10 extending in a widthwise direction thereof. When each of the fuel cells 3 generates the electricity uniformly over the electricity-generable region 130 thereof, the magnetic flux density increases as approaching the current output terminal 21 substantially in proportion to a distance to the current output terminal 21.

If no electrochemical reaction is developed in a portion of the electricity-generable region 130 of one or some of the fuel cells 3 which coincides with an area A, as illustrated in FIG. 16, of the plate body 20 of the current collector plate 10 in the lengthwise direction of the fuel cell stack 1, it will cause no current or a weak current to appear at the area A of the plate body 20. Therefore, in an area B next to the area A of the plate body 20, the current flows which is produced by portions of the fuel cells 3 spatially coinciding with the area B in the lengthwise direction of the fuel cell stack 1, so that the current density in the area B will be smaller than that when all the fuel cells 3 are operating normally to produce the electricity uniformly over the electricity-generable region 130s thereof.

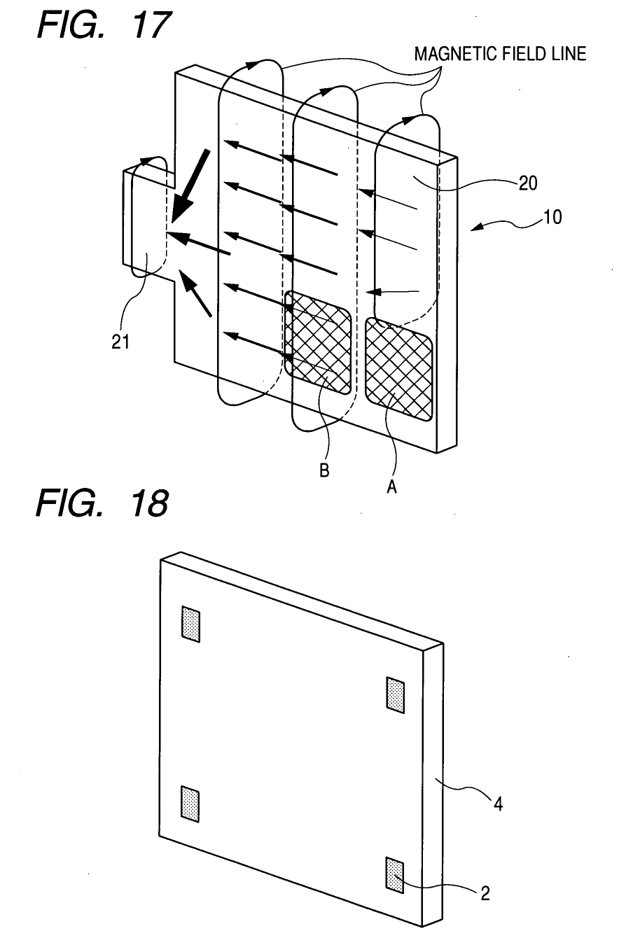

Accordingly, if no flow of current appears at the area A of the current collector plate 10, it will cause, as illustrated in FIG. 17, no magnetic field to be produced around the area A and the magnetic flux density around the area B to decrease. This results in changes in the magnetic flux density around the areas A and B from when all of the fuel cells 3 are operating normally to produce the electricity uniformly over the electricity-generable region 130s thereof. Such changes are detected by the magnetic sensors 2 which are, as illustrated in FIG. 13, installed in the insulating plates 4. In other words, each of the magnetic sensors 2 of this embodiment functions to detect a change in the magnetic flux density around the current collector plate 10 as indicating a change in the magnetic flux density around the length of the fuel cell stack 1 (i.e., a change in current distribution in the fuel cell stack 1).

The controller 6, like the first embodiment, works to monitor changes in outputs from the magnetic sensor 2 arising from a change in current distribution in the fuel cell stack 1, specify one of the first to sixth factors, as described above, which results in the current drop in ability of the fuel cell stack 1 to generate the electricity, and take a corresponding one of the measures, as discussed in the first embodiment, to recover the amount of electricity generated by the whole of the fuel cell stack 1.

Each of the current collector plates 10 preferably has a constant thickness in order to minimize a variation in magnetic flux density in a vertical direction of the current collector plate 10 when the fuel cell stack 1 is operating normally.

In some cases, when one of the fuel cells 3 has failed to partially generate the electricity, that is, it has the electrochemical reaction disabled area 140, so that no flow of current appears, for example, at the area A of FIG. 16, flows of current produced by portions of the other fuel cells 3 spatially coinciding with the electrochemical reaction disabled area 140 may bypass the electrochemical reaction disabled area 140 and concentrates at a portion of the current collector plate 10 other than the area A, thus resulting in an increase in magnetic flux density in that portion. Even in such an event, the increase in magnetic flux density may be detected by one of the magnetic sensors 2 to specify the cause and location resulting in a drop in ability of the fuel cell stack 1 to generate the electricity.

Referring back to FIG. 13, the three magnetic sensors 2 are bonded to or embedded in each of the insulating plates 4 in abutment with the current collector plates 10. The insulating plates 4 are made of, for example, a glass epoxy resin which does not disturb the magnetic field produced around the current collector plates 10. The number of the magnetic sensors 2 used, as already described in the first embodiment, is not limited to the one illustrated in FIG. 13. For example, the one magnetic sensor 2 may be installed on either of the insulating plates 4.

FIG. 18 illustrates an example where the four magnetic sensors 2 are embedded in corners of one of the insulating plates 4. This layout is suitable for detecting a change in magnetic flux density of the magnetic field around the current collector plate 10 which arises from a drop in ability to generate the electricity at any of four locations: portions of the electricity-generable region 130 near the air inlet 331 and the air outlet 333 of the air-side separator 33 and the hydrogen inlet 341 and the hydrogen outlet 343 of the hydrogen-side separator 34.

While the present invention has been disclosed in terms of the preferred embodiments in order to facilitate better understanding thereof, it should be appreciated that the invention can be embodied in various ways without departing from the principle of the invention. Therefore, the invention should be understood to include all possible embodiments and modifications to the shown embodiments which can be embodied without departing from the principle of the invention as set forth in the appended claims.

1. A fuel cell control apparatus comprising:
a magnetic sensor working to output a signal as a function of a magnetic flux density of a magnetic field produced around a fuel cell stack through which an electrical current, as generated by electrochemical reaction taken place in each of fuel cells, flows, the fuel cell stack being made up of a stack of fuel cells arrayed adjacent each other; and
a controller designed to analyze the signal outputted from said magnetic sensor to detect a change in the magnetic flux density arising from a drop in ability of the fuel cell stack to generate electricity which is to occur partially in the fuel cell stack, said controller working to take a predetermined measure to control an operation of the fuel cell stack for eliminating the drop in ability of the fuel cell stack to generate the electricity, and
wherein said magnetic sensor is disposed on a middle of the fuel cell stack in a direction in which the fuel cells are arrayed.

2. A fuel cell control apparatus as set forth in claim 1, wherein said controller compares a value of the signal outputted from said magnetic sensor with a reference value predetermined on a condition that the fuel cell stack is operating normally to produce a required amount of electricity, when a difference between the value of the signal and the reference value is found, said controller taking the predetermined measure to eliminate the drop in ability of the fuel cell stack.

3. A fuel cell control apparatus as set forth in claim 1, wherein said magnetic sensor is located to be sensitive to a selected portion of the magnetic field produced around one of the fuel cells.

4. A fuel cell control apparatus as set forth in claim 3, wherein said magnetic sensor is affixed to a selected portion of the one of the fuel cells.

5. A fuel cell control apparatus as set forth in claim 3, wherein said magnetic sensor is disposed in a selected portion of the one of the fuel cells.

6. (canceled)

7. A fuel cell control apparatus as set forth in claim 1, wherein each of the fuel cells is made of a unit including an assembly of an electrolyte film, a fuel electrode, and an air electrode, a fuel-side separator, and an air-side separator, the fuel-side separator and the air-side separator being affixed to the fuel electrode and the air electrode, respectively, and wherein said magnetic sensor is disposed on one of the fuel-side separator and the air-side separator.

8. A fuel cell control apparatus as set forth in claim 1, wherein each of the fuel cells is made of a unit including an assembly of an electrolyte film, a fuel electrode, and an air electrode, a fuel-side as a function a magnetic flux density of the portion of the magnetic field, and wherein said controller compares values of the signals outputted from said magnetic sensor and said second magnetic sensor with reference values predetermined on a condition that the fuel cell stack is operating normally to produce a required amount of electricity, when a difference between at least one of the values of the signals and a corresponding one of the reference values is found, said controller selecting one of predetermined measures to eliminate the difference.

12. A fuel cell control apparatus as set forth in claim 1, wherein a current collector is disposed on one of ends of the fuel cell stack from which the electric current produced by the fuel cell stack is outputted, and wherein said magnetic sensor is disposed to sensitive to a magnetic field, as produced by the electric current flowing through the current collector.

13. A fuel cell system comprising:
a fuel cell stack made up of a plurality of fuel cells assembled into a stack, said fuel cell stack working to produce an electric current flowing therethrough in a direction in which the fuel cells are assembled into the stack;
a magnetic sensor working to output a signal as a function of a magnetic flux density of a magnetic field which is produced around said fuel cell stack and arises from a flow of the electric current; and
a controller designed to analyze the signal outputted from said magnetic sensor to detect a change in the magnetic flux density caused by a drop in ability of said fuel cell stack to produce the electric current which is to occur partially in said fuel cell stack, said controller working to take a predetermined measure to control an operation of said fuel cell stack for eliminating the drop in ability of the fuel cell stack to produce the electric current, and
wherein said magnetic sensor is disposed on a middle of the fuel cell stack in the direction in which the fuel cells are assembled.

14. A fuel cell system as set forth in claim 13, wherein said controller compares a value of the signal outputted from said magnetic sensor with a reference value predetermined on a condition that the fuel cell stack is operating normally to produce a required amount of electricity, when a difference between the value of the signal and the reference value is found, said controller taking the predetermined measure to eliminate the drop in ability of the fuel cell stack.

15. A fuel cell system as set forth in claim 13, wherein said magnetic sensor is located to be sensitive to a selected portion of the magnetic field produced around one of the fuel cells.

16. A fuel cell system as set forth in claim 15, wherein said magnetic sensor is affixed to a selected portion of the one of the fuel cells.

17. A fuel cell system as set forth in claim 15, wherein said magnetic sensor is disposed in a selected portion of the one of the fuel cells.

18. (canceled)

19. A fuel cell system as set forth in claim 13, wherein each of the fuel cells is made of a unit including an assembly of an electrolyte film, a fuel electrode, and an air electrode, a fuel-side separator, and an air-side separator, the fuel-side separator and the air-side separator being affixed to the fuel electrode and the air electrode, respectively, and wherein said magnetic sensor is disposed on one of the fuel-side separator and the air-side separator.

20. A fuel cell system as set forth in claim 13, wherein each of the fuel cells is made of a unit including an assembly of an electrolyte film, a fuel electrode, and an air electrode, a fuel-side separator, and an air-side separator, the fuel-side separator and the air-side separator being affixed to the fuel electrode and the air electrode, respectively, and wherein said magnetic sensor is installed in one of the fuel-side separator and the air-side separator.

21. A fuel cell system as set forth in claim 15, wherein when the change in the magnetic flux density is detected, said controller selects one of predetermined measures which corresponds to the selected portion of the magnetic field and performs the one of the

24. A fuel cell system as set forth in claim 13, wherein a current collector is disposed on one of ends of the fuel cell stack from which the electric current produced by the fuel cell stack is outputted, and wherein said magnetic sensor is disposed to sensitive to a magnetic field, as produced by the electric current flowing through the current collector.

25. A method of measuring a current distribution in a fuel cell stack which is made up of a plurality of fuel cells which are arrayed adjacent each other and each of which is made up of a first and a second separator and an assembly nipped between the first and second separators, the assembly including an electrolyte, an air electrode affixed to a first surface of the electrolyte, and a fuel electrode affixed to a second surface of the electrolyte opposite the first surface, comprising:
providing a magnetic sensor on a circumference of the fuel cell stack perpendicular to a stack direction in which the fuel cells are arrayed and at a middle of the fuel cell stack in the stack direction to measure a magnetic field as generated by a flow of an electric current through the fuel cell stack in the stack direction; and
determining a current distribution in the fuel cell stack from the magnetic field measured by the magnetic sensor.

26. (canceled)

27. A method as set forth in claim 25, further providing additional magnetic sensors on the circumference of the fuel cell stack.

28. A fuel cell stack comprising:
a plurality of fuel cells assembled into a stack, each of the fuel cells being made up of an electrolyte, an air electrode affixed to a first surface of the electrolyte, a fuel electrode affixed to a second surface of the electrolyte opposite the first surface, and separators with gas flow paths which nip an assembly of the electrolyte, the air electrode, and the fuel electrode therebetween; and
a magnetic sensor disposed on a circumference of the stack perpendicular a stack direction that is a direction in which the fuel cells are assembled into the stack and at a middle of the stack in the stack direction.

29. (canceled)

30. A fuel cell stack as set forth in claim 28, further comprising additional sensors disposed on the circumference of the stack.

31. A fuel cell stack as set forth in claim 28, further comprising a current distribution determining circuit working to determine a current distribution in the stack using an output of said magnetic sensor produced as a function of a change in magnetic flux density.

32. A method of controlling an operation of a fuel cell stack which is made up of a plurality of fuel cells which are arrayed adjacent each other and each of which is made up of a first and a second separator and an assembly nipped between the first and second separators, the assembly including an electrolyte, an air electrode affixed to a first surface of the electrolyte, a fuel electrode affixed to a second surface of the electrolyte opposite the first surface, comprising:
determining a distribution of amount of electricity generated by the fuel cell stack based on a magnetic field which is produced by an electric current flowing through the fuel cell stack in a stack direction that is a direction in which the fuel cells are arrayed and measured by a magnetic sensor disposed on a middle of the fuel cell stack in the stack direction; and
controlling a supply of a gas to the fuel cell stack based on the distribution of amount of electricity.

33. (canceled)

34. A method as set forth in claim 32, wherein additional sensors disposed on a circumference of the stack.

35. A method as set forth in claim 32, wherein said controlling step controls a flow rate of the gas supplied to one of the air electrode and the fuel electrode or humidity of the gas.

36. A method of measuring a current distribution in a fuel cell stack which includes a plurality of fuel cells which are arrayed adjacent each other and each of which is made up of a first and a second separator and an assembly nipped between the first and second separators, the assembly including an electrolyte, an air electrode affixed to a first surface of the electrolyte, and a fuel electrode affixed to a second surface of the electrolyte opposite the first surface, a current collector being disposed on one of ends of the fuel cell stack which are opposed to each other in a stack direction that is a direction in which the fuel cells are arrayed for outputting an electric current, as generated by the fuel cell stack, in a direction perpendicular to the stack direction, comprising:
providing a magnetic sensor on a central portion of the one of ends of the fuel cell stack to measure a magnetic field as generated by a flow of an electric current through the current collector, the central portion being defined in a direction perpendicular to the stack direction; and
determining a current distribution in the fuel cell stack from the magnetic field measured by the magnetic sensor.

37. A method as set forth in claim 36, wherein the current collector is a current collector plate, and wherein the magnetic sensor works to measure the magnetic field around the current collector plate.

38. A method as set forth in claim 36, further providing additional magnetic sensors on the one of ends of the fuel cell stack.

39. A fuel cell stack comprising:
a plurality of fuel cells assembled into a stack, each of the fuel cells being made up of an electrolyte, an air electrode affixed to a first surface of the electrolyte, a fuel electrode affixed to a second surface of the electrolyte opposite the first surface, and separators with gas flow paths which nip an assembly of the electrolyte, the air electrode, and the fuel electrode therebetween;
a current collector disposed on one of ends of the stack of the fuel cells which are opposed to each other in a stack direction that is a direction in which the fuel cells are arrayed, for outputting an electric current, as generated by said fuel cell stack; and
a magnetic sensor working to measure a magnetic filed produced around said current collector, said magnetic sensor being installed on a central portion of the one of ends of the stack of the fuel cells, the central portion being defined in a direction perpendicular to the stack direction.

40. A fuel cell stack as set forth in claim 39, wherein the current collector is a current collector plate, and wherein said magnetic sensor works to measure the magnetic field around the current collector plate.

41. A fuel cell stack as set forth in claim 39, further comprising additional magnetic sensors on the one of ends of the stack of the fuel cells.

42. A fuel cell stack as set forth in claim 39, further comprising a current distribution determining circuit working to determine a current distribution in the stack of the fuel cells using an output of said magnetic sensor produced as a function of a change in magnetic flux density of the magnetic field.

43. A method of controlling an operation of a fuel cell stack which includes a plurality of fuel cells which are arrayed adjacent each other and each of which is made up of a first and a second separator and an assembly nipped between the first and second separators, the assembly including an electrolyte, an air electrode affixed to a first surface of the electrolyte, and a fuel electrode affixed to a second surface of the electrolyte opposite the first surface, a current collector being disposed on one of ends of the fuel cell stack which are opposed to each other in the stack direction for outputting an electric current, as generated by the fuel cell stack, in a direction perpendicular to the stack direction, comprising:
determining a distribution of amount of electricity generated by the fuel cell stack based on a magnetic field which is produced by an electric current flowing through the current collector and measured by a magnetic sensor installed on a central portion of the one of ends of the fuel cell stack, the central portion being defined in a direction perpendicular to the stack direction; and
controlling a supply of a gas to the fuel cell stack based on the distribution of amount of electricity.

44. A method as set forth in claim 43, wherein the current collector is a current collector plate, and wherein the magnetic sensor works to measure the magnetic field around the current collector plate.

45. A method as set forth in claim 43, further providing additional magnetic sensors on the one of the ends of the fuel cell stack.

46. A method as set forth in claim 43, wherein said controlling step controls a flow rate of the gas supplied to one of the air electrode and the fuel electrode or humidity of the gas.

47. A fuel cell stack comprising:
a plurality of fuel cells assembled into a stack, each of the fuel cells being made up of an electrolyte, an air electrode affixed to a first surface of the electrolyte, a fuel electrode affixed to a second surface of the electrolyte opposite the first surface, and separators with gas flow paths which nip an assembly of the electrolyte, the air electrode, and the fuel electrode therebetween;
a magnetic sensor working to measure a magnetic filed produced around said fuel cell stack, said magnetic sensor being installed in a central portion of an outer periphery of one of opposed faces of one of the separators, the opposed faces each extending in a direction perpendicular to a stack direction that is a direction in which the fuel cells are assembled into the stack.

48. A fuel cell stack as set forth in claim 47, wherein each of the electrolyte and the separators is of a substantially square shape, and wherein the central portion in which said magnetic sensor is installed is a central portion of one of sides of the one of the opposed faces of the one of the separators.

49. A fuel cell stack as set forth in claim 48, wherein said magnetic sensor is installed in a recess formed in the one of the separators which faces the air electrode.

50. A fuel cell stack as set forth in claim 49, wherein the recess is formed in an area of the one of the separators which is isolated from areas of the first and second surfaces of the electrolyte to which the air electrode and the fuel electrode are affixed.

51. A fuel cell stack as set forth in claim 50, wherein said magnetic sensor includes two sensor elements one of which is sensitive to a magnetic flux flowing in a y-direction on a plane extending perpendicular to a width of the one of the separators and the other of which is sensitive to a magnetic flux flowing in an x-direction perpendicular to the y-direction.
